(19) United States
(12) Patent Application Publication
(10) Pub. No.: US 2012/0256275 A1
(43) Pub. Date: Oct. 11, 2012

(54) METAL GATE STRUCTURE AND MANUFACTURING METHOD THEREOF

(76) Inventors: Hsin-Fu Huang, Tainan City (TW); Chi-Mao Hsu, Tainan City (TW); Kun-Hsien Lin, Hsinchu City (TW); Chin-Fu Lin, Tainan City (TW); Tzung-Ying Lee, Ping-Tung County (TW); Min-Chuan Tsai, New Taipei City (TW); Yi-Wei Chen, Taichung City (TW); Bin-Siang Tsai, Changhua County (TW); Ted Ming-Lang Guo, Tainan City (TW); Ger-Pin Lin, New Taipei City (TW); Yu-Ling Liang, Changhua County (TW); Yen-Ming Chen, New Taipei City (TW); Tsai-Yu Wen, Tainan City (TW)

(21) Appl. No.: 13/081,479

(22) Filed: Apr. 6, 2011

(51) Int. Cl. H01L 29/772; H01L 21/283

(52) U.S. Cl. 257/410; 438/592; 257/E29.242; 257/E21.159

(57) ABSTRACT

A manufacturing method of a metal gate structure includes first providing a substrate having a dummy gate formed thereon. The dummy gate includes a high-K gate dielectric layer, a bottom barrier layer, a first etch stop layer and a sacrificial layer sequentially and upwardly stacked on the substrate. Then, the sacrificial layer is removed to form a gate trench with the first etch stop layer exposed on the bottom of the gate trench. After forming the gate trench, a first work function metal layer is formed in the gate trench.

### BACKGROUND OF THE INVENTION

1. Field of the Invention

The invention relates to a metal gate structure and a manufacturing method thereof, and more particularly, to a metal gate structure and a manufacturing method applied with the gate last process.

2. Description of the Prior Art

Polysilicon is conventionally used as the gate electrode in a semiconductor device, such as the metal-oxide-semiconductor (MOS) transistor. However, with a trend toward scaling down the size of the semiconductor device, the conventional polysilicon gate has faced problems such as inferior performance due to boron penetration and unavoidable depletion effect which increases equivalent thickness of the gate dielectric layer, reduces gate capacitance, and worsens a driving force of the devices. Therefore, work function metals are used to replace the conventional polysilicon gate to be the control electrode that competent to the high dielectric constant (high-K) gate dielectric layer.

The conventional dual metal gate methods are categorized into the gate first process and the gate last process. In a conventional dual metal gate method applied with the gate first process, the anneal process for forming the source/drain ultra-shallow junction, and the silicide process are performed after forming the metal gate. The thermal budgets always make the gate first process face challenges for material choices. Consequently, the gate last process is developed to provide more material choices for the high-K gate dielectric layer and the metal gate, and thus replaces the gate first process.

Please refer to FIG. 1, which is a schematic drawing illustrating an n-type metal gate structure formed by a conventional manufacturing method. As shown in FIG. 1, according to the conventional gate last process, a substrate 100 is provided with a dummy gate or a replacement gate (not shown) formed thereon. The dummy gate includes a high-K gate dielectric layer 102, a titanium nitride (TiN) layer 104 serving as a bottom barrier layer, and a polysilicon layer (not shown). After forming elements for the n-type transistor and p-type transistor such as the lightly-doped drains (LDDs), the spacers, and the source/drain, and other elements such as the silicide and the inter-layer dielectric (ILD) layer, the polysilicon layer of the dummy/replacement gate is removed to form a gate trench 110 on the substrate 100. Subsequently, a tantalum nitride (TaN) layer 106 serving as an etch stop layer is formed on the substrate 100 and on the TiN layer 104 in the gate trench 110. The TaN layer 106 is exemplarily formed by an atomic layer deposition (ALD) technique. Then, a p-type work function metal layer 108 is formed. As shown in FIG. 1, the TaN layer 106 in the gate trench 110 has a U shape. It is noteworthy that when removing the polysilicon layer, the TiN layer 104 is used to protect the high-K gate dielectric layer 102 from the etchant. Accordingly the surface of the TiN layer 104 is damaged because it contacts the etchant directly. Furthermore, the ALD technique is to form a layer by absorption reactions between the process gas and the surface on which the layer is formed. Therefore, the damaged heterogeneous surface of the TiN layer 104 renders adverse impact to the formation of the ALD-TaN layer 106. It is found that the TaN layer 106 does not reach the predetermined thickness. Furthermore, the TaN layer 106 is formed with poor step coverage. As a result, the step coverage of the TaN layer 106 in the gate trench 110 is lower than 70%.

Next, the p-type work function metal layer 108 is removed, thus an n-type work function metal layer can be formed in the gate trench 110. It is noticeable that when removing the p-type work function metal layer 108, the TaN layer 106 serving as an etch stop layer is used to protect the underneath TiN layer 104 and high-K gate dielectric layer 102. However, since the TaN layer 106 has not reached its predetermined thickness and has had the poor step coverage, the TaN layer 106 is not resistible enough to the etchant. In other words, because the inferior formation of the TaN layer 106, the defective TaN layer 106 cannot protect the TiN layer 104, even the high-K gate dielectric layer, during removing the p-type work function metal layer 108. Therefore, the TiN layer 104, even the high-K gate dielectric layer 102, is contacted with the etchant and thus is damaged. Such defect leads to serious problems such as gate leakage.

Accordingly, though the gate last process is able to avoid processes of high thermal budget and to provide more material choices for the high-K gate dielectric layer and the metal gate, the gate last process still faces integrity requirements for the complicated processes and reliability requirement for the layers filling in the gate trench.

### SUMMARY OF THE INVENTION

According to an aspect of the present invention, there is provided a metal gate structure. The metal gate structure includes a high-K gate dielectric layer, a flat-shaped etch stop layer formed on the high-K gate dielectric layer, and at least a first work function metal layer formed on the flat-shaped etch stop layer.

According to another aspect of the present invention, there is provided a manufacturing method of a metal gate structure. The manufacturing method first provides a substrate having a dummy gate formed thereon. The dummy gate sequentially includes a high-K gate dielectric layer, a bottom barrier layer, a first etch stop layer, and a sacrificial layer. The manufacturing method then removes the sacrificial layer to form a gate trench on the substrate, such that the first etch stop layer is exposed on the bottom of the gate trench. The manufacturing method further includes forming a first work function metal layer in the gate trench.

According to the metal gate structure and the manufacturing method thereof provided by the present invention, a metal gate structure having a flat-shaped first etch stop layer is provided. The flat-shaped first etch stop layer is formed on the bottom barrier layer or the high-K gate dielectric layer before the etching process that is used to remove the sacrificial layer. In other words, the flat-shaped first etch stop layer is formed on an intact surface. Therefore, the flat-shaped first etch stop layer easily reaches the predetermined thickness and obtains a superior step coverage that beneficial to protect the underneath layers during the following etching processes. Thus, the reliability of the following formed metal gate structure is improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating an n-type metal gate structure formed by a conventional manufacturing method.

FIGS. 2-6 are schematic drawings illustrating a manufacturing method of a metal gate structure provided by a first preferred embodiment of the present invention.

FIGS. 2-3 and FIGS. 7-10 are schematic drawings illustrating a manufacturing method of a metal gate structure provided by a second preferred embodiment of the present invention.

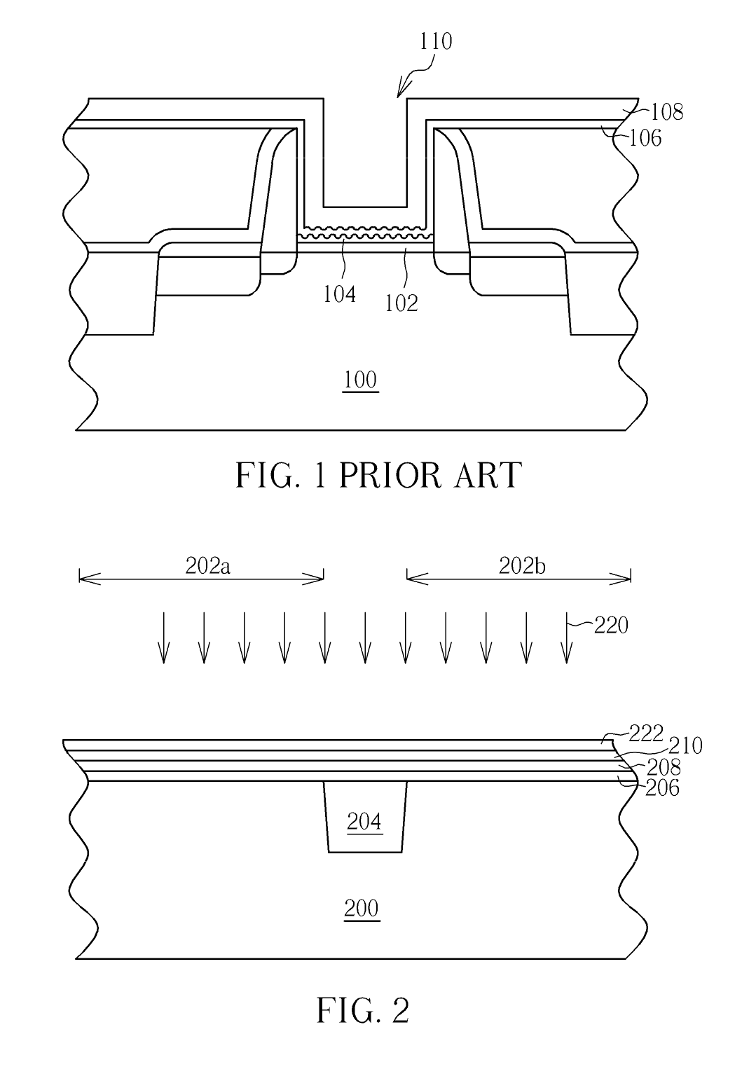

### DETAILED DESCRIPTION

Please refer to FIGS. 2-6, which are schematic drawings illustrating a manufacturing method of a metal gate structure provided by a first preferred embodiment of the present invention. It is noteworthy that the preferred embodiment is applied with the gate-last process. As shown in FIG. 2, the preferred embodiment first provides a substrate 200, such as a silicon substrate, a silicon-containing substrate, or a silicon-on-insulator (SOI) substrate. The substrate 200 includes a first active region 202a and a second active region 202b defined thereon. The substrate 200 also includes at least a shallow trench isolation (STI) 204 for electrically isolating the first active region 202a and the second active region 202b formed therein. Next, an interfacial layer 206, a high-K gate dielectric layer 208, a bottom barrier layer 210, and an etch stop layer 222 are sequentially formed on the substrate 200. According to the preferred embodiment, the interfacial layer 206 includes silicon oxide and the high-K gate dielectric layer 208 includes high-K material such as metal oxide. For instance, the high-K gate dielectric layer 208 includes rare earth metal oxide such as hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate, (SrBi₂Ta₂O₉, SBT), lead zirconate titanate (PbZrₓTi₁₋ₓO₃, PZT) or barium strontium titanate (BaₓSr₁₋ₓTiO₃, BST). The bottom barrier layer 210 preferably is a TiN layer, but not limited to this. The etch stop layer 222 preferably is a TaN layer, but not limited to this. The etch stop layer 222 can include material having etching rate different from the etching rates of polysilicon and of the bottom barrier layer 210.

It is noteworthy that the etch stop layer 222 is formed by an ALD method 220 in the preferred embodiment. As mentioned above, an ALD method is performed to form a layer by absorption reactions between the process gas and the surface on which the layer is formed. Therefore the result of the ALD method 220 is very susceptible to the surface characteristic of the pre-layer of the etch stop layer 222, that is the surface characteristic of the bottom barrier layer 210. In the preferred embodiment, the etch stop layer 222 is formed on the surface of the bottom barrier layer 210 by the ALD method 220 immediately after forming the bottom barrier layer 210. Because there is not any process performed to the bottom barrier layer 210, the surface of the bottom barrier layer 210 remains intact. Accordingly, the etch stop layer 222 is steadily formed on the bottom barrier layer 210 and reaches a predetermined thickness. More important, the step coverage of the etch stop layer 222 is improved to 100%.

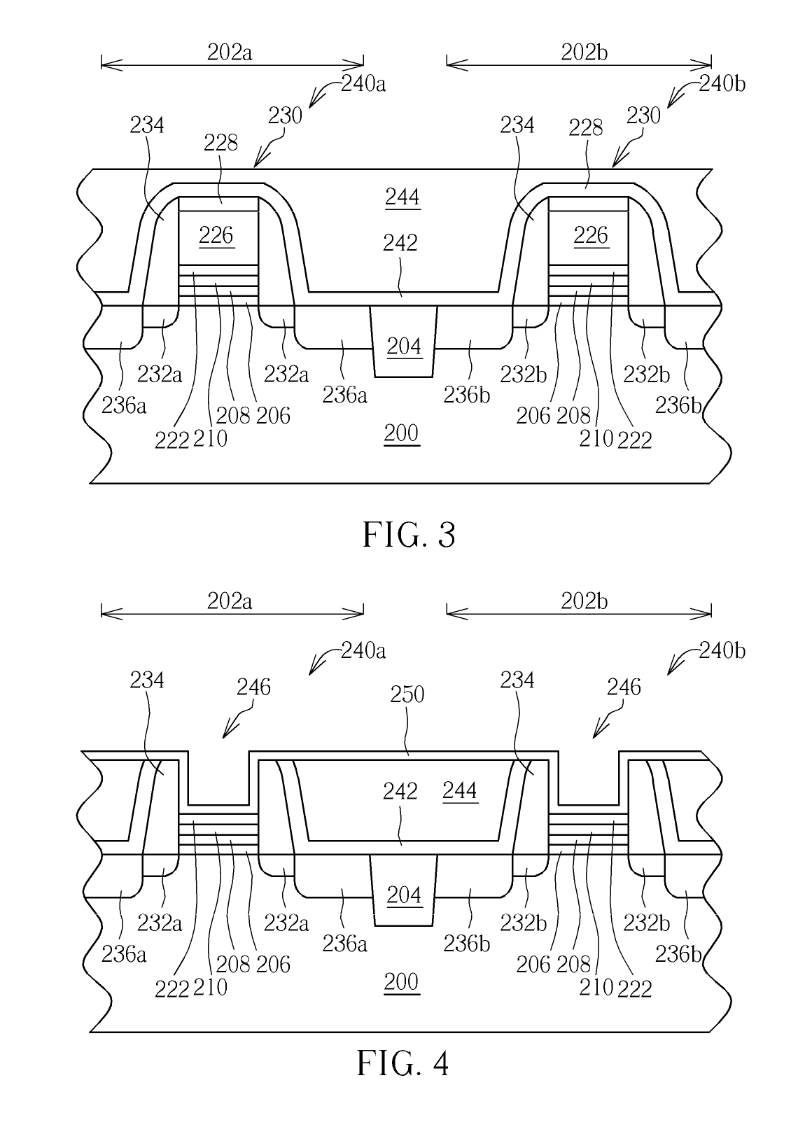

Please refer to FIG. 3. After forming the etch stop layer 222, a sacrificial layer 226 and a patterned hard mask 228 are sequentially formed on the substrate 200. Then, a patterning process is performed to etch the sacrificial layer 226, the etch stop layer 222, the bottom barrier layer 210, the high-K gate dielectric layer 208, and the interfacial layer 206 through the patterned hard mask 228. Consequently, dummy gates 230 are formed on the substrate 200 respectively in the first active region 202a and the second active region 202b. As shown in FIG. 3, the dummy gates 230 upwardly and sequentially include the interfacial layer 206, the high-K gate dielectric layer 208, the bottom barrier layer 210, the etch stop layer 222, the sacrificial layer 226, and the patterned hard mask 228. It is noteworthy that cross-sectional views of the interfacial layer 206, the high-K gate dielectric layer 208, the bottom barrier layer 210, the etch stop layer 222, and the sacrificial layer 226 respectively include a flat-shaped structure. In addition, the sacrificial layer 226 is a polysilicon layer in the preferred embodiment, but not limited to this.

Please still refer to FIG. 3. After forming the dummy gates 230, ion implantations with different conductivity type ions are sequentially performed to form first light doped drains (LDDs) 232a in the first active region 202a and second LDDs 232b in the second active region 202b, respectively at two sides of the dummy gates 230. Additionally, offset spacers (not shown) can be formed on sidewalls of the dummy gates 230 before forming the first LDDs 232a and the second LDDs 232b. Then, spacers 234 are formed on the sidewalls of the dummy gates 230. Following the formation of the spacers 234, ion implantations with different conductivity type ions are sequentially performed to form a first source/drain 236a in the first active region 202a and a second source/drain 236b in the second active region 202b, respectively at two sides of the spacers 234. Thus, a first conductivity type semiconductor device 240a and a second conductivity type semiconductor device 240b are obtained respectively in the first active region 202a and the second active region 202b. Furthermore, selective strain scheme (SSS) can be used in the preferred embodiment. For example, a selective epitaxial growth (SEG) method can be used to form the source/drain 236a/236b: When the first conductivity type semiconductor device 240a is a p-type semiconductor device and the second conductivity type semiconductor device 240b is an n-type semiconductor device, epitaxial silicon layers with silicon germanium (SiGe) can be used to form the p-type first source/drain 236a and epitaxial silicon layers with silicon carbide (SiC) can be used to form the n-type second source/drain 236b. Additionally, silicides (not shown) are formed on the surface of the first source/drain 236a and the surface of the second source/drain 236b. After forming the first conductivity type semiconductor device 240a and the second conductivity type semiconductor device 240b, a contact etch stop layer (CESL) 242 and an ILD layer 244 are sequentially formed on the substrate 200.

Please refer to FIG. 4. Then, a planarization process such as a chemical mechanical polishing (CMP) process is performed to remove a portion of the ILD layer 242, a portion of the CESL 242, and the patterned hard mask 228 to expose the sacrificial layer 226. After the planarization process, a proper etching process is performed to remove the sacrificial layer 226 to form a gate trench 246 respectively in the first active region 202a and the second active region 202b. It is noteworthy that in the preferred embodiment, the flat-shaped etch stop layer 222 is used to protect the underneath bottom barrier layer 210, the high-K gate dielectric layer 208, and the interfacial layer 206 during removing the sacrificial layer 226. Consequently, the flat-shaped etch stop layer 222 is exposed on the bottom of the gate trenches 246 after the etching process. After forming the gate trenches 246, a first work function metal layer 250 is formed on the flat-shaped etch stop layer 222 in the gate trenches 246 and on the substrate 200 as shown in FIG. 4. According to the preferred embodiment, the first work function metal layer 250 provides an appropriate work function for the first conductivity type semiconductor device 240a, that is the p-type semiconductor device 240a. Therefore, the first work function metal layer 250 has a first work function, and the first work function is between 4.8 eV and 5.2 eV.

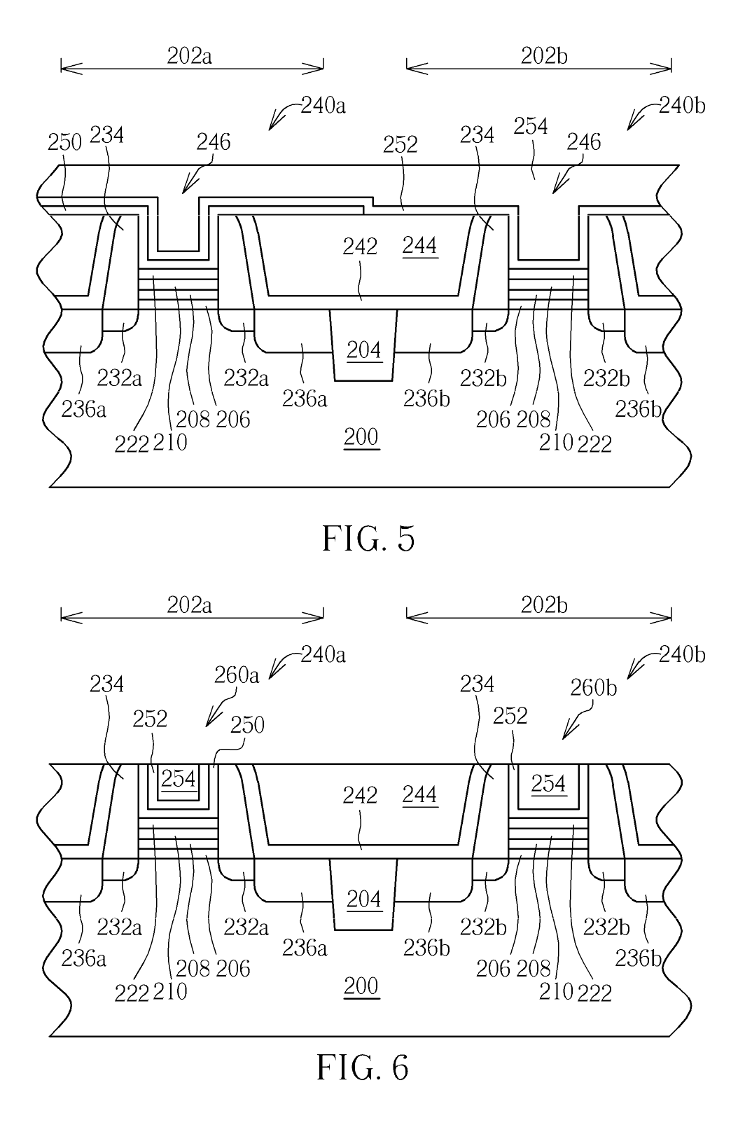

Please refer to FIG. 5. Next, the first work function metal layer 250 in the second active region 202b is removed. It is noticeable that the flat-shaped etch stop layer 222 is used to protect the underneath bottom barrier layer 210, high-K gate dielectric layer 208 and interfacial layer 206 during removing the first work function metal layer 250 in the preferred embodiment. Consequently, the flat-shaped etch stop layer 222 is exposed on the bottom of the gate trench 246 in the second active region 202b again after removing the first work function metal layer 250 in the second active region 202b. Thereafter, a second work function metal layer 252 and a filling metal layer 254 are sequentially formed in the gate trenches 246 and on the substrate 200 with the filling metal layer 254 filling up the gate trenches 246. As shown in FIG. 5, the second work function metal layer 252 and the filling metal layer 254 are sequentially formed on the first work function metal layer 250 in the gate trench 246 in the first active region 202a while the second work function metal layer 252 and the filling metal layer 254 are sequentially formed on the etch stop layer 222 in the gate trench 246 in the second active region 202b. In the preferred embodiment, the second work function metal layer 252 provides an appropriate work function for the second conductivity type semiconductor device 240b, that is the n-type semiconductor device 240b. Therefore, the second work function metal layer 252 has a second work function, and the second work function is between 3.9 eV and 4.3 eV. The filling metal layer 254 includes materials with low resistance and superior gap-filling characteristic, such as aluminum (Al), but not limited to this.

Please refer to FIG. 6. After forming the first work function metal layer 250, the second work function metal layer 252 and the filling metal layer 254, a CMP process is performed to remove the unnecessary filling metal layer 254, second work function metal layer 252 and first work function metal layer 250. Consequently, a first metal gate structure 260a of the first conductivity type semiconductor device 240a is formed in the first active region 202a and a second metal gate structure 260b of the second conductivity type semiconductor device 240b is formed in the second active region 202b. As shown in FIG. 6, cross-sectional views of the interfacial layer 206, the high-K gate dielectric layer 208, the bottom barrier layer 210 and the etch stop layer 222 of the first metal gate structure 260a respectively are flat-shaped, and cross-sectional views of the first work function metal layer 250 and the second work function metal layer 252 of the first metal gate structure 260a respectively are U-shaped. Still as shown in FIG. 6, cross-sectional views of the interfacial layer 206, the high-K gate dielectric layer 208, the bottom barrier layer 210 and the etch stop layer 222 of the second metal gate structure 260b respectively are flat-shaped and a cross-sectional view of the second work function metal layer 252 of the second metal gate structure 260b is U-shaped. In addition, the ILD layer 244 and the CESL 242 can be selectively removed and sequentially reformed on the substrate 200 for improving performance of the semiconductor devices 240a/240b in the preferred embodiment.

According to the metal gate structure and the manufacturing method thereof provided by the first preferred embodiment, the metal gate structures 260a/260b are provided with the flat-shaped etch stop layer 222. Because the flat-shaped etch stop layer 222 is formed on the bottom barrier layer 210 before removing the sacrificial layer 226 and before removing a portion of the first work function metal layer 250, the flat-shaped etch stop layer 222 is formed on an intact heterogeneous surface. Accordingly, the flat-shaped etch stop layer 222 formed by the ALD method 220 easily reaches the predetermined thickness and obtains a superior step coverage up to 100%. Therefore the flat-shaped etch stop layer 222 renders superior protection to the underneath bottom barrier layer 210, high-K gate dielectric layer 208 and interfacial layer 206 during the following etching processes. Thus the reliability of the following formed metal gate structure 260a/260b is improved.

Please refer to FIGS. 2-3 and FIGS. 7-10, which are schematic drawings illustrating a manufacturing method of a metal gate structure provided by a second preferred embodiment of the present invention. Because the steps of providing a substrate 200 and sequentially forming an interfacial layer 206, a high-K gate dielectric layer 208, a bottom barrier layer 210 and an etch stop layer 222 on the substrate 200 are the same in both of the first preferred embodiment and the second preferred embodiment, those details are omitted in the interest of brevity, and the same elements are designated by the same numerals as shown in FIG. 2. In the same concept, because the steps of forming the first conductivity type semiconductor device 240a in the first active region 202a and the second conductivity type semiconductor device 240b in the second active region 202b, of forming the elements of the semiconductor device 240a/240b, and of forming dummy gates 230 are the same in both of the first and second preferred embodiment, those details are also omitted in the interest of brevity, and the same elements are designated by the same numerals as shown in FIG. 3. Additionally, material choices for elements the same in the first and the second embodiments are omitted herein in the interest of brevity.

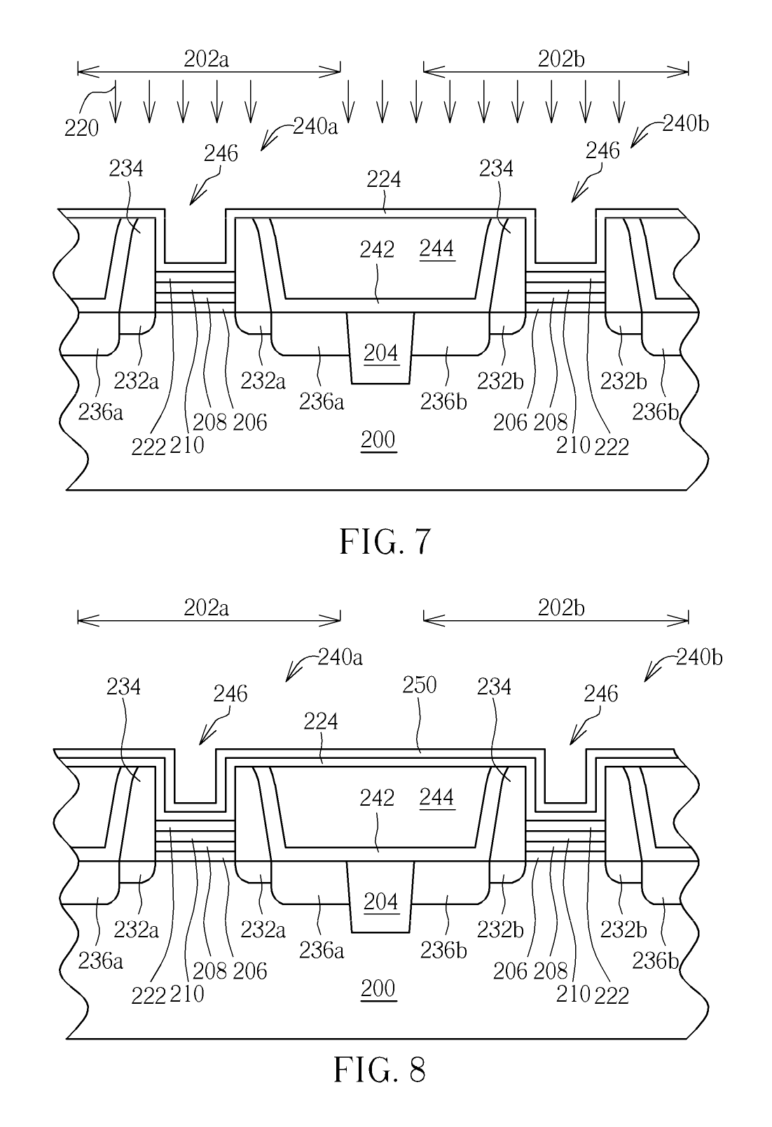

Please refer to FIG. 7. The difference between the second preferred embodiment and the first preferred embodiment is: After exposing the sacrificial layer 226 by a CMP process and removing the sacrificial layer 226 to form a gate trench 246 respectively in the first active region 202a and the second active region 202b by an etching process, the ALD method 220 is performed again. As mentioned above, because the etch stop layer 222 is used to protect the bottom barrier layer 210, the high-K gate dielectric layer 208 and the interfacial layer 206 during removing the sacrificial layer 226, the flat-shaped etch stop layer 222 is exposed on the bottom of the gate trench 246. Subsequently, an etch stop layer 224 is formed on the flat-shaped etch stop layer 222 in the gate trenches 246 and on the substrate 200 by the ALD method 220. A thickness of the etch stop layer 224 is smaller than a thickness of the etch stop layer 222. And the etch stop layer 222 and the etch stop layer 224 include the same material: TaN. It is noteworthy that though the surface of etch stop layer 222 may be damaged in the etching process used to remove the sacrificial layer 226, the etch stop layer 224 is still formed on a homogeneous surface because the etch stop layer 224 and the etch stop layer 222 share the same material. In other words, since the etch stop layer 224 is formed on the homogenous surface of the etch stop layer 222, a step coverage of the etch stop layer 224 reaches 100%.

Please refer to FIG. 8. After forming the etch stop layer 224, a first work function metal layer 250 is formed on the etch stop layer 224 in the gate trench 246 and on the substrate 200. According to the preferred embodiment, the first work function metal layer 250 provides an appropriate work function for the first conductivity type semiconductor device 240a, that is the p-type semiconductor device 240a. Therefore, the first work function metal layer 250 has a first work function, and the first work function is between 4.8 eV and 5.2 eV.

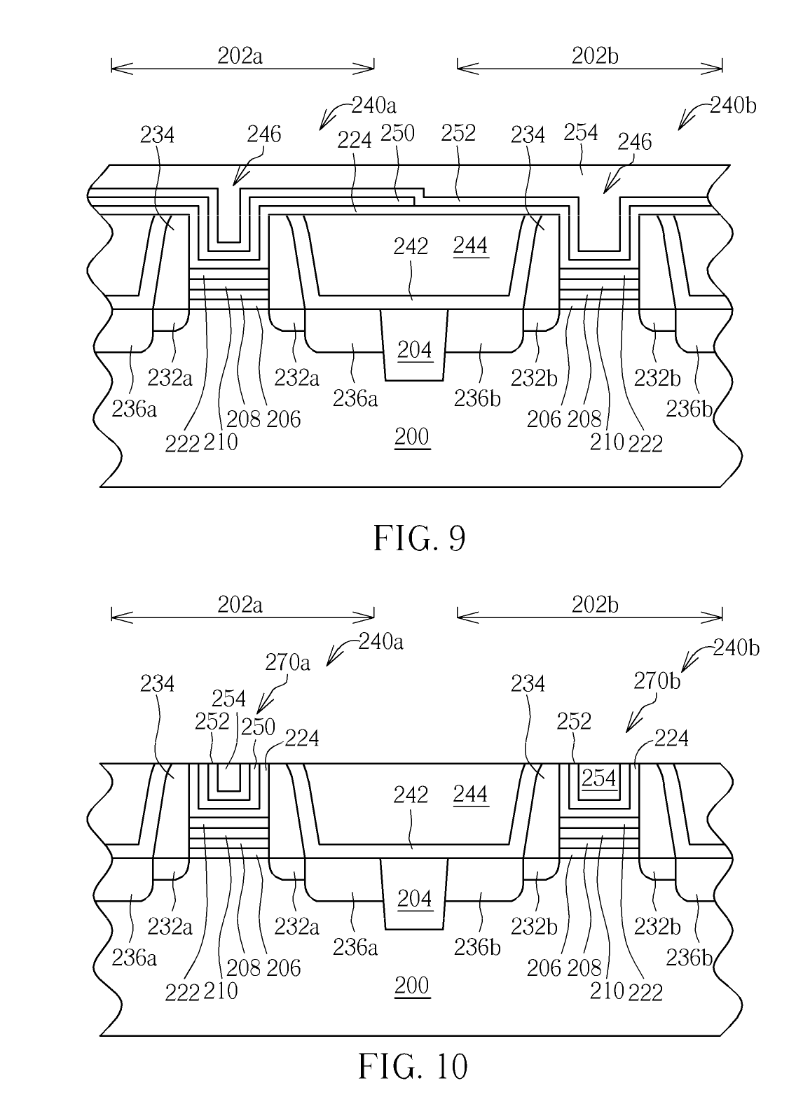

Please refer to FIG. 9. Then, the first work function metal layer 250 in the second active region 202b is removed. It is noticeable that in the preferred embodiment, the etch stop layer 224 is used to protect the underneath bottom barrier layer 210, high-K gate dielectric layer 208 and interfacial layer 206 during removing a portion of the first work function metal layer 250. Consequently, the etch stop layer 224 is exposed on the bottom of the gate trench 246 in the second active region 202b after removing the first work function metal layer 250. Thereafter, a second work function metal layer 252 and a filling metal layer 254 are sequentially formed on the substrate 200 with the filling metal layer 254 filling up the gate trenches 246. As shown in FIG. 9, the second work function metal layer 252 and the filling metal layer 254 are sequentially formed on the first work function metal layer 250 in the gate trench 246 in the first active region 202a while the second work function metal layer 252 and the filling metal layer 254 are sequentially formed on the etch stop layer 224 in the gate trench 246 in the second active region 202b. In the preferred embodiment, the second work function metal layer 252 provides an appropriate work function for the second conductivity type semiconductor device 240b, that is the n-type semiconductor device 240b. Therefore, the second work function metal layer 252 has a first work function, and the first work function is between 3.9 eV and 4.3 eV. As mentioned above, the filling metal layer 254 includes materials with low resistance and superior gap-filling characteristic, such as Al, but not limited to this.

Please refer to FIG. 10. After forming the first work function metal layer 250, the second work function metal layer 252 and the filling metal layer 254, a CMP process is performed to remove the unnecessary filling metal layer 254, second work function metal layer 252 and first work function metal layer 250. Consequently, a first metal gate structure 270a of the first conductivity type semiconductor device 240a is formed in the first active region 202a and a second metal gate structure 270b of the second conductivity type semiconductor device 240b is formed in the second active region 202b. As shown in FIG. 10, cross-sectional views of the interfacial layer 206, the high-K gate dielectric layer 208, the bottom barrier layer 210 and the etch stop layer 222 of the first metal gate structure 270a respectively are flat-shaped, and cross-sectional views of the etch stop layer 224, the first work function metal layer 250 and the second work function metal layer 252 of the first metal gate structure 270a respectively are U-shaped. Still as shown in FIG. 10, cross-sectional views of the interfacial layer 206, the high-K gate dielectric layer 208, the bottom barrier layer 210 and the etch stop layer 222 of the second metal gate structure 270b respectively are flat-shaped and cross-sectional views of the etch stop layer 224 and the second work function metal layer 252 of the second metal gate structure 270b respectively are U-shaped. In addition, the ILD layer 244 and the CESL 242 can be selectively removed and sequentially reformed on the substrate 200 for improving performance of the semiconductor devices 240a/240b in the preferred embodiment.

According to the metal gate structure and the manufacturing method thereof provided by the second preferred embodiment, the metal gate structures 270a/270b are provided with the flat-shaped etch stop layer 222 and the U-shaped etch stop layer 224. Because the flat-shaped etch stop layer 222 is formed on the bottom barrier layer 210 before removing the sacrificial layer 226, the flat-shaped etch stop layer 222 is formed on an intact heterogeneous surface. Accordingly, the flat-shaped etch stop layer 222 formed by the ALD method 220 easily reaches the predetermined thickness and obtains a superior step coverage up to 100%. Therefore the flat-shaped etch stop layer 222 renders superior protection to the underneath bottom barrier layer 210, high-K gate dielectric layer 208 and interfacial layer 206 during the following etching processes. Furthermore, because the U-shaped etch stop layer 224 is formed on the flat-shaped etch stop layer 222 before removing a portion of the first work function metal layer 250, more particularly, the U-shaped etch stop layer 224 is formed on a homogenous surface of the flat-shaped etch stop layer 222. Accordingly, the U-shaped etch stop layer 224 formed by the ALD method 220 easily reaches the predetermined thickness and obtains a superior step coverage up to 100%. Therefore the U-shaped etch stop layer 224 also renders superior protection to the underneath bottom barrier layer 210, high-K gate dielectric layer 208 and interfacial layer 206 during the following etching processes. Thus the reliability of the following formed metal gate structures 270a/270b is improved.

According to the metal gate structure and the manufacturing method provided by the present invention, a metal gate structure having a flat-shaped etch stop layer and a U-shaped etch stop layer is provided. The flat-shaped etch stop layer is formed on the bottom barrier layer or the high-K gate dielectric layer before the etching process that is used to remove the sacrificial layer. In other words, the flat-shaped etch stop layer is formed on an intact surface. Accordingly, the flat-shaped etch stop layer easily reaches the predetermined thickness and obtains a superior step coverage. The U-shaped etch stop layer is formed on the homogenous surface of the flat-shaped etch stop layer, therefore the U-shaped etch stop layer also easily reaches the predetermined thickness and obtains a superior step coverage. Therefore the flat-shaped etch stop layer and the U-shaped etch stop layer render superior protection to the underneath layers during the following etching processes. Thus the reliability of the following formed metal gate structure is improved.

Those skilled in the art will readily observe that numerous modifications and alterations of the device and method may be made while retaining the teachings of the invention.

What is claimed is:

1. A metal gate structure comprising:
a high dielectric constant (high-K) gate dielectric layer;
a flat-shaped etch stop layer formed on the high-K gate dielectric layer; and
at least a first work function metal layer formed on the flat-shaped etch stop layer.

2. The metal gate structure according to claim 1, further comprising a bottom barrier layer positioned between the high-K gate dielectric layer and the flat-shaped etch stop layer.

3. The metal gate structure according to claim 1, further comprising an interfacial layer, and the high-K gate dielectric layer is formed on the interfacial layer.

4. The metal gate structure according to claim 1, further comprising a U-shaped etch stop layer positioned between the flat-shaped etch stop layer and the first work function metal layer.

5. The metal gate structure according to claim 4, wherein the flat-shaped etch stop layer and the U-shaped etch stop layer comprise the same material.

6. The metal gate structure according to claim 1, wherein the first work function metal layer comprises a first work function, and the first work function is between 3.9 eV and 4.3 eV.

7. The metal gate structure according to claim 1, further comprising a second work function metal layer positioned between the flat-shaped etch stop layer and the first work function metal layer.

8. The metal gate structure according to claim 7, wherein the second work function metal layer comprises a second work function, and the second work function is between 4.8 eV and 5.2 eV.

9. The metal gate structure according to claim 1, further comprising a filling metal layer positioned on the first work function metal layer.

10. A manufacturing method of a metal gate structure comprising:
providing a substrate having a dummy gate formed thereon, the dummy gate sequentially comprising a high-K gate dielectric layer, a bottom barrier layer, a first etch stop layer, and a sacrificial layer;
removing the sacrificial layer to form a gate trench on the substrate, and the first etch stop layer being exposed on the bottom of the gate trench; and
forming a first work function metal layer in the gate trench.

11. The manufacturing method of a metal gate structure according to claim 10, wherein the dummy gate further comprises an interfacial layer formed between the high-K gate dielectric layer and the substrate.

12. The manufacturing method of a metal gate structure according to claim 10, wherein the first etch stop layer is formed by an atomic layer deposition (ALD) method.

13. The manufacturing method of a metal gate structure according to claim 10, wherein a cross-sectional view of the first etch stop layer is flat-shaped.

14. The manufacturing method of a metal gate structure according to claim 10, further comprising performing an ALD method to form a second etch stop layer in the gate trench after removing the sacrificial layer.

15. The manufacturing method of a metal gate structure according to claim 14, wherein a cross-sectional view of the second etch stop layer is U-shaped.

16. The manufacturing method of a metal gate structure according to claim 10, wherein the first work function metal layer comprises a first work function, and the first work function is between 4.8 eV and 5.2 eV.

17. The manufacturing method of a metal gate structure according to claim 16, further comprising sequentially forming a second work function metal layer and a filling metal layer on the first work function metal layer in the gate trench.

18. The manufacturing method of a metal gate structure according to claim 17, wherein the second work function metal layer comprises a second work function, and the second work function is between 3.9 eV and 4.3 eV.

19. The manufacturing method of a metal gate structure according to claim 16, further comprising:
removing the first work function metal layer in the gate trench to expose the first etch stop layer in the gate trench; and
sequentially forming a second work function metal layer and a filling metal layer on the first etch stop layer in the gate trench.

20. The manufacturing method of a metal gate structure according to claim 19, wherein the second work function metal layer comprises a second work function, and the second work function is between 3.9 eV and 4.3 eV.
